(19) United States
(12) Patent Application Publication
(10) Pub. No.: US 2004/0157398 A1
(43) Pub. Date: Aug. 12, 2004

(54) Method for fabricating a transistor

(76) Inventor: Dong Yeal Keum, Icheon-si (KR)

Correspondence Address: GROSSMAN & FLIGHT LLC, Suite 4220, 20 North Wacker Drive, Chicago, IL, 60606-6357, US

(21) Appl. No.: 10/747,601

(22) Filed: Dec. 29, 2003

(30) Foreign Application Priority Data
Dec. 30, 2002 (KR) 10-2002-0087305

(51) Int. Cl. H01L 21/336

(52) U.S. Cl. 438/305

(57) ABSTRACT

A method for fabricating a transistor is disclosed. An example method forms a gate electrode on a semiconductor substrate, forms a first preliminary source/drain region and a pocket junction region through a first ion implantation process using the gate electrode as a mask, the pocket junction region being formed under the first preliminary source/drain region. The example method also forms a first oxide layer with uniform thickness on the substrate including the gate electrode, forms a nitride layer with uniform thickness on the first oxide layer, forms a second oxide layer over the nitride layer and forms spacers on sidewalls of the gate electrode. In addition, the example method forms a second preliminary source/drain region through a second ion implantation process using the spacers as a mask, removes the nitride layer and the first oxide layer on the surface of the substrate, and diffuses substantially all of the implanted ions in a horizontal direction of the substrate by performing a thermal treatment process for the resulting substrate.

### FIELD OF THE DISCLOSURE

The present disclosure relates generally to semiconductor devices and, more particularly, to a method for fabricating a transistor with an LDD (lightly doped drain) region.

### BACKGROUND

In general, with the rapid spread of intelligent devices such as computers, semiconductor devices are rapidly being developed. Recently, semiconductor devices are required to have high storage-capability as well as to operate at a high speed. To meet these requirements, technologies for manufacturing semiconductor devices are being developed to satisfy the higher demand for integration, reliability, operating speed. As a result of this trend, semiconductor devices with a micro pattern are being developed and the channel length of transistors on a semiconductor substrate is being rapidly reduced.

FIG. 1 illustrates a cross-sectional view of a transistor made according to a conventional fabricating method. As shown in FIG. 1, a transistor according to the conventional method comprises a gate electrode 12, a source/drain region 16a and 16b with an LDD (lightly doped drain) region. Spacers 14 are formed on the sidewalls of the gate electrode 12, on a substrate 10. The gate electrode 12 comprises a gate oxide 12b and a gate poly 12a. In addition, a pocket junction region 18 is formed at the sides of the lightly doped drain (LDD) region of the source/drain region 16a and 16b. The pocket junction region 18 can mitigate the occurrence of punch-through and current leakage in a transistor.

However, the punch-through in the bulk of a silicon wafer is more likely to occur as transistor size is scaled down. Such punch-through cannot be prevented only by the pocket junction. Moreover, the functional limitations of ion implantation equipment present difficulty in reducing the junction depth without limit.

### BRIEF DESCRIPTION OF THE DRAWINGS

FIG. 1 illustrates a cross-sectional view of a transistor made according to a conventional fabricating method.

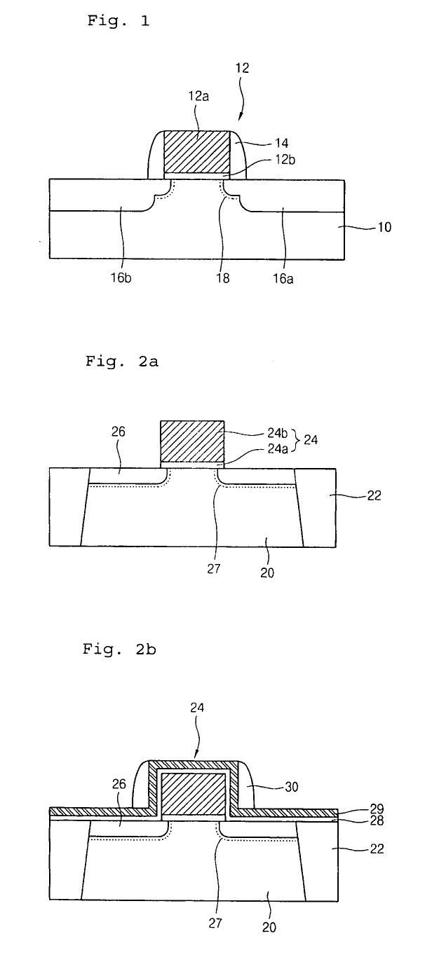

FIGS. 2a through 2d illustrate, in cross-sectional views, an example fabricating process of an example transistor.

### DETAILED DESCRIPTION

As described in greater detail below, an example fabricating method is capable of reducing the junction depth of a source/drain region with an LDD region, as a transistor's size decreases. More specifically, one example method forms a gate electrode on a substrate with an active region defined by a device isolation layer, forms a first preliminary source/drain region and a pocket junction region through a first ion implantation process using the gate electrode as a mask, the pocket junction region being formed under the first preliminary source/drain region. In addition, the example method forms a first oxide layer with uniform thickness on the substrate including the gate electrode, forms a nitride layer with uniform thickness on the first oxide layer, forms a second oxide layer over the nitride layer, forms spacers on sidewalls of the gate electrode by performing an etch back process for the second oxide layer, forms a second preliminary source/drain region through a second ion implantation process using the spacers as a mask, removes the nitride layer and the first oxide layer on the surface of the substrate, and diffuses the implanted ions only in a horizontal direction of the substrate by performing a thermal treatment process for the resulting substrate. In addition, the example fabricating method may further comprise performing a thermal treatment process prior to the removal of the nitride layer and the first oxide layer.

By forming spacers consisting of a first oxide layer, a nitride layer, and a second oxide layer on the sidewalls of a gate electrode and performing a thermal treatment process, the example fabrication methods described herein may easily reduce the junction depth of a source/drain region with an LDD region.

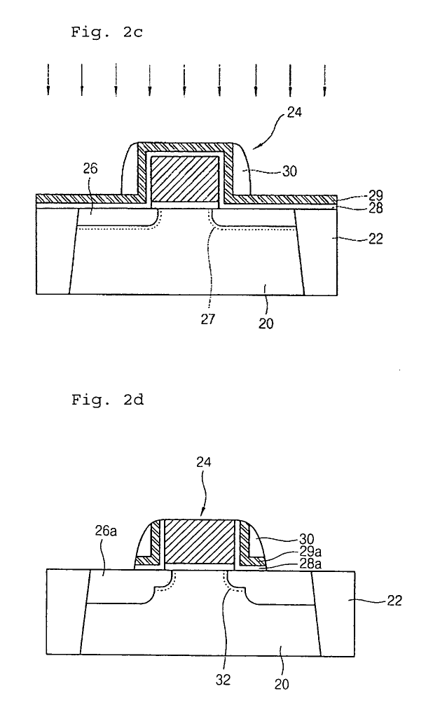

Referring to FIG. 2a, a substrate 20 with an active region defined by a device isolation layer 22 is provided. The device isolation layer 22 is preferably a trench oxide layer. The trench oxide layer is generally used for device isolation in fabricating a semiconductor device with a micro pattern. Another example of the device isolation layer is a field oxide layer.

Then, an oxide layer and a polysilicon layer are formed in sequence on the substrate 20. A photoresist pattern is formed on the polysilicon layer by photolithography. The oxide layer and the polysilicon layer are etched using the photoresist pattern as a mask to form a gate poly 24b and a gate oxide 24a. As a result, a gate electrode 24 comprising the gate poly 24b and the gate oxide 24a is formed on the substrate 20.

Next, a first ion implantation process is performed using the gate electrode 24 as a mask to form a first preliminary source/drain region 26 at both sides of the gate electrode 24 in the substrate 20. Here, to prevent surface punch-trough in a transistor, a pocket junction region 27 is formed under the first preliminary source/drain region 26.

Referring to FIG. 2b, a first oxide layer 28 with uniform thickness is formed on the substrate 20 including the gate electrode 24. A nitride layer 29 with uniform thickness is formed on the first oxide layer 28. A second oxide layer is formed over the nitride layer 29. Then, an etch back process is applied to the second oxide layer to form spacers 30 on the sidewalls of the gate electrode 24. Here, the nitride layer 29 functions as an etch-stop layer during the etch back process.

Referring to FIG. 2c, a second ion implantation process is performed using the spacers 30 as a mask to form a second preliminary source/drain region in the substrate 20. During the ion implantation process, the depth of the ion implantation is controlled by means of the nitride layer 29 and the first oxide layer 28. Therefore, the implanted ions are placed in a shallower area of the substrate 20. Then, a thermal treatment process may be performed for the resulting substrate 20, additionally. Through the thermal treatment, the ions implanted in the substrate 20 are diffused along with the surface of the substrate 20 because the nitride layer 29 prevents the diffusion of ions.

Referring to FIG. 2d, the nitride layer 29 and the first oxide layer 28 on the surface of the substrate are removed. As a result, the gate electrode 24 with a spacer structure is formed on the structure 20. The spacer structure is a multi-layer structure comprising a first oxide layer 28a, a nitride layer 29a, and a second oxide layer 30.

Next, a thermal treatment process is performed for the resulting substrate 20. Through the thermal treatment, the junction depth of a source/drain region 26a is easily controlled. In other words, the source/drain region 26a with a shallow junction is formed. The shallow junction is formed because the nitride layer 29a of the spacer structure prevents diffusion of the ions during the thermal treatment. A pocket junction region 32 remains at the sides of the LDD (lightly doped drain) region of the source/drain region 26a.

Therefore, the example fabrication method can easily form a source/drain region with shallow junction. The example fabrication method is applicable to a fabricating process of a semiconductor device being continuously scaled down (i.e., made using smaller pattern features). In addition, the example fabrication method may be used to overcome the functional limitations of semiconductor fabricating equipments by a fabrication process that embodies a source/drain region with shallow junction. Consequently, the present invention can enhance productivity and reliability in fabricating a semiconductor device.

Although certain methods and apparatus have been described herein, the scope of coverage of this patent is not limited thereto. To the contrary, this patent covers all embodiments fairly falling within the scope of the appended claims either literally or under the doctrine of equivalents.

What is claimed is:

1. A method for fabricating a transistor comprising:
forming a gate electrode on a semiconductor substrate;
forming a first preliminary source/drain region and a pocket junction region through a first ion implantation process using the gate electrode as a mask, the pocket junction region being formed under the first preliminary source/drain region;
forming a first oxide layer with uniform thickness on the substrate including the gate electrode;
forming a nitride layer with uniform thickness on the first oxide layer;
forming a second oxide layer over the nitride layer;
forming spacers on sidewalls of the gate electrode;
forming a second preliminary source/drain region through a second ion implantation process using the spacers as a mask;
removing the nitride layer and the first oxide layer on the surface of the substrate; and
diffusing substantially all of the implanted ions in a horizontal direction of the substrate by performing a thermal treatment process for the resulting substrate.

2. The method as defined by claim 1, further comprising performing a thermal treatment process prior to the removal of the nitride layer and the first oxide layer.
